(19) United States
(12) Patent Application Publication
(10) Pub. No.: US 2007/0044832 A1
(43) Pub. Date: Mar. 1, 2007

(54) PHOTOVOLTAIC TEMPLATE

(76) Inventor: Leslie G. Fritzemeier, Fairport, NY (US)

Correspondence Address: Christopher B. Miller;Jaeckle Fleischmann & Mugel, LLP, 190 Linden Oaks, Rochester, NY, 14625-2812, US

(21) Appl. No.: 11/467,009

(22) Filed: Aug. 24, 2006

Related U.S. Application Data
(60) Provisional application No. 60/711,392, filed on Aug. 25, 2005.

(51) Int. Cl. H01L 31/00

(52) U.S. Cl. 136/252

(57) ABSTRACT

A template for growth of an anticipated semiconductor film has a deformation textured substrate. The template also has an intermediate epitaxial film coupled to the deformation textured substrate, the intermediate epitaxial film being chemically compatible and substantially lattice matched with the anticipated semiconductor film. A method of manufacturing a template for the growth of an anticipated semiconductor is also disclosed. A substrate is deformed to produce a textured surface. An intermediate epitaxial film, chemically compatible and substantially lattice matched with the anticipated semiconductor film, is deposited. A further disclosed photovoltaic device has a semiconductor layer, a deformation textured substrate, and an intermediate epitaxial film coupled to the deformation textured substrate. The intermediate epitaxial film is chemically compatible and substantially lattice matched with the semiconductor layer. The semiconductor layer is epitaxially grown on the intermediate epitaxial film.

### RELATED APPLICATIONS

This application claims priority to U.S. provisional patent application 60/711,392, entitled, “Crystalline Thin Film Photovoltaic Template” filed Aug. 25, 2005, which is hereby officially incorporated by reference in its entirety.

### GOVERNMENT FUNDING

The claimed invention was made with Government support under Grant DE-FG02-06ER84585 awarded by the Department of Energy. The Government has certain rights to the claimed invention.

The claimed invention was also made in the performance of a Cooperative Research and Development Agreement with the Department of the Air Force. The Government of the United States has certain rights to use the claimed invention.

### FIELD

The claimed invention relates to photovoltaic templates, and more specifically to a photovoltaic template suitable for the epitaxial growth of semiconducting compounds, the template providing a chemically compatible, lattice matched epitaxial growth surface.

### BACKGROUND

Based at the very least on the premise that natural resources such as gas and oil are of a limited supply, scientists and engineers are continually striving for new ways to reliably and affordably manufacture and supply energy while minimizing the environmental impact. Photovoltaic cells, more commonly known as solar cells, are one device which has been developed to help fill this energy need. The basic principle behind a photovoltaic cell is that energy in the form of light can be harnessed and converted into a voltage which can be used to power electrical devices. Photovoltaic technology dates back to 1839 when it was discovered that two electrodes placed in a conductive solution would produce an electric current when light was shined on the solution. In 1941, the first silicon solar cell was invented. Many improvements have been made since then to the solar cell, but the continual problem facing the widespread adoption of photovoltaic technology is that the photovoltaic cells are very expensive to manufacture, do not provide enough power to be practical, are hard to be manufactured in useful shapes, and/or cannot be manufactured reliably in large sizes.

FIG. 1 schematically illustrates a side cross-section of one type of photovoltaic device 20 for the purpose of a general explanation of how such a photovoltaic device 20 can work. The heart of the photovoltaic device 20 is made from two semiconductor layers which are each “doped” to have different semiconductive properties and/or which intrinsically have different semiconductive properties. In general, semiconductor materials with different properties can be grouped into two groups: “n-type” and “p-type”. An n-type semiconductor has an abundance of weakly bound free electrons, either intrinsically, or from a process known as “doping.” As a result, the abundant electrons in an n-type semiconductor are very mobile. A p-type semiconductor has a lack of weakly-bound free electrons, either intrinsically, or from a doping process which interferes with an atom's covalent bonds creating an electron “hole.” As a result, the holes in a p-type semiconductor material are eager to receive free electrons.

The example photovoltaic device 20 has a bottom p-type layer 22 and a top n-type layer 24. A junction 26 naturally forms at the interface between the n-type layer 24 and the p-type later 22. In the junction, some of the free-electrons from the n-type layer 24 have moved into the p-type layer 22 to fill the holes therein. As a result, the junction 26 becomes non-conductive, and at some point, the free electrons and holes can no longer move through the junction 26. This creates an electric field across the junction 26 which will end tip being proportional to the voltage of the photovoltaic device 20.

The photovoltaic device 20 may be oriented so that incident light 28 will pass through the n-type layer 24 (which is sometimes called a window layer) and then into contact with the p-type layer 22. Ideally, the p-type layer 22 in this type of device should have a high absorptivity for the wavelengths of light which are incident 28. The incident light 28 can be thought of as being made of photons, or light energy. Some of the incident light 28 photons will be absorbed by the n-type layer 24, and some of the incident light 28 photons will be absorbed by the p-type layer 22. The absorbed photons separate or free electron-hole pairs in both materials. The electric field at the junction 26 will cause free electrons to move to the n-type layer 24, and it will also cause free holes to move to the p-type layer 22.

A transparent conductor 30 or an array of conducting filaments is typically coupled on top of the n-type layer 24 in this type of embodiment. The photovoltaic device 20 also has a substrate 32 for support of the photovoltaic device 20. The substrate 32 can also be conductive. The substrate 32 is coupled to the p-type 22 layer by an ohmic contact 34 which can either act as the conductor discussed above if the substrate 32 is not conductive, or it can act as an interface between the p-type layer 22 and the substrate 32.

If a conductive current path is provided between the n-type layer 24 and the p-type layer 22, then the excess electrons which the incident light 28 causes to be built up in the n-type layer 24 will pass through the conductive path and be reunited with holes in the p-type layer 22. This can be accomplished, for example, by coupling one side of a load 36 to the transparent conductor 30 and another side of the load 36 to the substrate 32. Excess electrons generated by the incident light 28 will move 38 through the load 36, providing current through the load. Based on the current supplied by the moving electrons and the voltage from the electric field at the junction 26, power (the product of the voltage and the current) is supplied to the load 36. Therefore, at least in theory, photovoltaic devices are very useful devices.

Unfortunately, single junction thin-film photovoltaic devices are rather inefficient, with practical cells exhibiting incident light conversion to power efficiencies of less than ten percent. Crystalline silicon cell conversion efficiencies are typically 12-15%, with special devices approaching 20%. Unfortunately, crystalline silicon costs are high and material usage is inefficient. Other types of photovoltaic devices exist, including one with multiple junctions from a plurality of semiconductor layers. These multijunction photovoltaic devices have been demonstrated with conversion efficiencies over 30%. The current draw-back to multijunction photovoltaic devices, however, is that they are very expensive. Multijunction photovoltaic devices have been most advantageously grown on single crystal germanium or single crystal GaAs substrates which often cost over $10,000 per square meter.

Emerging low cost photovoltaic technologies include ribbon-grown silicon, polymeric/organic films, and nanotechnology-based approaches (numerous). None of these newer solutions fully addresses the Solar Energy Industry and Department of Energy Roadmap goals for increased production volume, increased efficiency and lower cost per watt generated

Therefore, what is needed is a method for the low-cost production of large areas of high-efficiency photovoltaic devices.

### SUMMARY

A template for growth of an anticipated semiconductor film has a deformation textured substrate. The template also has an intermediate epitaxial film coupled to the deformation textured substrate, the intermediate epitaxial film being chemically compatible and substantially lattice matched with the anticipated semiconductor film.

A method of manufacturing a template for the growth of an anticipated semiconductor is disclosed. A substrate is deformed to produce a textured surface. An intermediate epitaxial film, chemically compatible and substantially lattice matched with the anticipated semiconductor film, is deposited.

A photovoltaic device has a semiconductor layer, a deformation textured substrate, and an intermediate epitaxial film coupled to the deformation textured substrate. The intermediate epitaxial film is chemically compatible and substantially lattice matched with the semiconductor layer. The semiconductor layer is epitaxially grown on the intermediate epitaxial film.

A photovoltaic cell has a flexible deformation textured substrate and a metal intermediate epitaxial film coupled to the flexible deformation substrate. The photovoltaic cell also has a photovoltaic stack comprising a homojunction, heterojunction or multijunction photovoltaic stack coupled to the metal intermediate epitaxial film. The photovoltaic cell further has at least one electrode coupled to the photovoltaic stack to provide a path for electrical current from incident photons.

A photovoltaic module has an array of photovoltaic cells electrically coupled together and supported by a support structure. The photovoltaic module also has a transparent protective cover protecting the array of photovoltaic cells. At least one photovoltaic cell in the array of photovoltaic cells has a semiconductor layer, a deformation textured substrate, and an intermediate epitaxial film coupled to the deformation textured substrate. The intermediate epitaxial film is chemically compatible and substantially lattice matched with the semiconductor layer. The semiconductor later is epitaxially grown on the deformation textured substrate.

A method of manufacturing a photovoltaic device is disclosed. A textured metal is produced. A transition metal soluble in both the textured metal and a refractory element is deposited. An epitaxial layer is deposited on the transition metal. Semiconductor layers are deposited on the epitaxial layer.

It is an object of the claimed invention to provide an epitaxial growth template with a chemically-compatible, lattice-matched surface for the growth of semiconducting films with quality and performance approaching films produced on single crystal substrates.

It is another object of the claimed invention to provide an economically and commercially viable process for the deposition of epitaxial films on biaxially textured metal or alloy substrates suitable for use in scale-up and manufacturing processes.

### BRIEF DESCRIPTION OF THE DRAWINGS

FIG. 1 schematically illustrates a side cross-section of one type of photovoltaic device.

FIG. 2 schematically illustrates an embodiment of a template for growth of an anticipated semiconductor film.

FIG. 3 is a pole diagram based on an embodiment of a molybdenum intermediate epitaxial film on a nickel deformation textured substrate.

FIG. 4 is a pole diagram based on an embodiment of a molybdenum intermediate epitaxial film on a copper deformation textured substrate.

FIG. 5 is a pole diagram based on an embodiment of a combination niobium and nickel intermediate epitaxial film on a copper deformation substrate.

FIG. 6 schematically illustrates one embodiment of a photovoltaic template manufacturing process.

FIG. 7 schematically illustrates an embodiment of a semiconductor fabrication process.

FIG. 8 schematically illustrates one embodiment of a photovoltaic device.

FIG. 9 schematically illustrates one embodiment of a flexible photovoltaic cell.

FIG. 10 schematically illustrates one embodiment of a photovoltaic module.

### DETAILED DESCRIPTION

The claimed invention will be primarily described in connection with the formation of epitaxial body-centered cubic intermediate layers deposited onto a biaxially textured face centered-cubic nickel (Ni) or copper (Cu) surface that has been formed by deformation processing. Such embodiments are intended to be for purposes of illustration and do not limit the scope of the claimed invention, which is intended to be determined solely by the claims and their equivalents. It will be apparent that other epitaxial layers can be deposited on other substrate metals and alloys

FIG. 2 schematically illustrates an embodiment of a template 40 for growth of an anticipated semiconductor film. The template 40 has a deformation textured substrate 42. Suitable deformation textured substrates may be produced, having sharp textures approaching single crystal quality, in pure metals using techniques in metal deformation which are known to those skilled in the art.

Face centered cubic (fcc) metals, to some extent body centered cubic (bcc) metals and some alloys based on fcc metals are especially useful for a deformation substrate 42 material, as they can be biaxially textured using well known rolling deformation and annealing processes. A well-known texture in fcc metals and alloys is the so called “cube texture”, in which the c-axis of the substrate crystallites is substantially perpendicular to the substrate surface, and the a-axes align primarily along the direction of rolling. The cube texture can often be made with very low full-width at half-maximum (FWHM) values obtained from X-ray pole figures, an indication of collective alignment of both c- and a-axes of all crystallites. Under controlled rolling and annealing processes, these deformation textured metal tapes possess texture approaching that of single crystals. In some embodiments of a substrate deformation process, the FWHM texture is less than 10 degrees and more typically less than 5 degrees, although other FWHM textures may be desirable outside of that range. The preferred growth surface texture has grain boundary misorientations averaging less than 3 degrees, although some may be less than 5 degrees or less than 10 degrees.

Examples of suitable metals which can be used for the deformation textured substrate 42 include, but are not limited to nickel, a nickel alloy, copper, or a copper alloy. An intermediate epitaxial film 44 is coupled to deformation textured substrate 42, the intermediate epitaxial film 44 being chemically compatible and substantially lattice matched with an anticipated semiconductor film, in particular with a compound semiconductor. “Lattice matched”, as used herein, means that the intermediate epitaxial film 44 possesses a crystal structure and lattice constant sufficiently close to the deformation textured substrate 42 and/or a semiconducting material intended to be used with the template 40 to allow the epitaxial growth of any intermediate layers and the subsequent growth of high performance semiconducting films. In addition, the intermediate epitaxial film 44 will act as a barrier to inhibit deformation textured substrate 42 element(s) from migrating to the surface of the intermediate epitaxial film 42 and/or to any following layers and interfering with the initial growth of the intended semiconducting layer or contaminating the semiconducting layer.

Examples of materials which can be used as an intermediate epitaxial film 44 include, but are not limited to, elements from Group 5b and/or Group 6b of the periodic table of elements; V, Cr, Nb, Mo, Ta, W and/or the elements silicon and germanium; any of these elements in an alloy; and/or any combination of the previous. In some embodiments, the intermediate epitaxial film 44 can be functional, for example, it can serve as an ohmic layer, or as a conductor layer in a photovoltaic cell.

The biaxial texture of the deformation textured substrate 42 is preferably reproduced in the texture of the intermediate epitaxial film 44 as a result of the epitaxial growth used to couple the intermediate epitaxial film 44 to the deformation textured substrate 42. As used herein, “biaxial” means that the crystal grains in the substrate 42 or film 44 are in close alignment with both a direction perpendicular to the surface of the film 44 and a direction in the plane of the film 44. Biaxial texturing allows for the production of a low volume of point and line defects in a semiconducting film which might be then grown on the template 40. This biaxial texturing minimizes the current carrier trapping effects of high angle grain boundaries allowing the achievement of very high current carrier densities in these films at typical device operating conditions.

Deposition of the intermediate epitaxial film 44 can be done in a vacuum process such as molecular beam epitaxy, evaporation or sputtering, or by chemical vapor deposition, or by electrochemical means such as electroplating (with or without electrodes). Other methods of depositing the intermediate epitaxial film 44 may be apparent to those skilled in the art or developed by those skilled in the art and are intended to be within the scope of the appended claims.

The template 40 of FIG. 2 enables the low-cost production of state-of-the-art photovoltaic devices since the substrate materials may be less expensive than traditional substrates. Photovoltaic devices produced on templates such as the embodiments discussed with regard to FIG. 2 will have crystalline structures with small amounts of defects enabling high efficiency conversion of light, such as natural sunlight, to electricity at a very low cost when compared to the prior art.

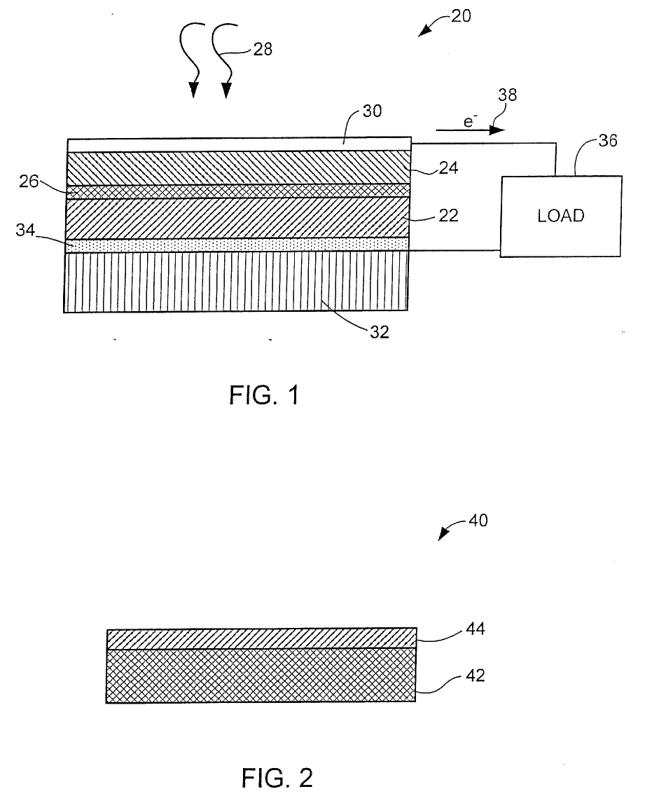

The highest demonstrated efficiencies for the conversion of sunlight to electricity have been demonstrated by multijunction cells. A multi-junction photovoltaic device is similar to the example solar cell of FIG. 1, but having a plurality of p-n (or p-i-n) junctions formed by more than one interface between differing semiconductor materials. Multijunction films consist of a series of p-n Junctions formed from different compound semiconducting materials, sometimes also including silicon homo- or heterojunctions. Each junction absorbs light of a slightly different energy, effectively utilizing more of the light spectrum. Example semiconducting compounds which may be used in a multijunction thin film device include, but are not limited to, GaAs, InGaP, InGaAlAs, etc. The performance of these compounds is very sensitive to lattice strain, so a highly lattice matched template is required.

Two types of templates used and contemplated in the prior art are germanium or GaAs single crystal templates and polycrystalline germanium films grown on molybdenum foil or on molybdenum films on glass substrates. Germanium or GaAs single crystal templates have been used because they are:
a) Chemically compatible with the semiconducting compounds
b) An excellent lattice match with the semiconducting compounds
c) An extrinsic semiconductor (potentially adding efficiency to the cell)

Unfortunately, single crystal germanium is extremely expensive. The pre-existing alternative to the use of bulk single crystal germanium is the germanium-on-molybdenum films which are known to be:
a) Chemically compatible with the semiconducting compounds
b) An excellent lattice match with the semiconducting compounds
c) Typically formed with a good ‘sheet’ texture.

However, the polycrystalline germanium films do not possess controlled in-plane texture, so semiconducting films must be growth with very large grain sizes to overcome the reduction in properties due to the local misorientation. The issue with this approach is that it is not readily scalable to practical manufacturing and will still be limited in performance.

The production of biaxially textured diamond-cubic or body-centered-cubic intermediate layers lattice matched to the semiconducting compound films on deformation textured substrates has not been anticipated in the literature.

The following examples describe previously unrealized templates for the large area growth of low cost semiconductors.

### EXAMPLE 1

Copper metal can be produced with a very strong crystallographic texture using rolling and heat treatment processes that have been known for decades. Copper is relatively inexpensive, and is over 5 times lower in cost than the high purity nickel or nickel alloy substrates.

A desired surface for the deposition of compound semiconductor materials is germanium. However, copper diffuses very rapidly through germanium and copper and germanium together form a low-melting point phase that inhibits the ability to process the combined materials. Nickel also diffuses very rapidly through germanium so a nickel surface layer is not optimum for germanium growth. Nickel and copper also diffuse rapidly through silicon, so nickel or copper are not optimum surfaces for silicon layer growth.

Refractory elements such as molybdenum, niobium and other Group 5b and 6b elements provide an effective barrier to copper diffusion. These elements and copper exhibit little, if any, mutual solubility in the solid phase at or above room temperature. The prior work of Fritzemeier et al (U.S. Pat. No. 6,730,410) indicated that these elements could not be grown directly on copper or copper alloy substrates without the imposition of a high cost noble metal layer (Pd). This example provides a method to produce an epitaxial Group 5b or 6b metal layer directly on copper.

Deformation textured copper and nickel foils were prepared using conventional rolling deformation and annealing processes. Copper and nickel in the form of strips were rolled to a final thickness of about 0.050 mm, ensuring at least 99% reduction in thickness from start to finish. The rolled foil was annealed in a vacuum atmosphere for 60 minutes at 750 C for copper and 1000 C for nickel to ensure the formation of a strong recrystallization texture. Optimum times and temperatures can be dependent on desired economics of the process as well as desired degree of texture and desired final grain size. The copper and nickel substrates exhibit a high degree of cube texture, with a (111)-type pole figure FWHM of less than 5 degrees as measured by x-ray diffraction.

Molybdenum films were deposited on the nickel and copper foils using magnetron sputtering at a temperature of 650 C, in 2 mTorr argon gas and at a rate of 1.5 nm/second.

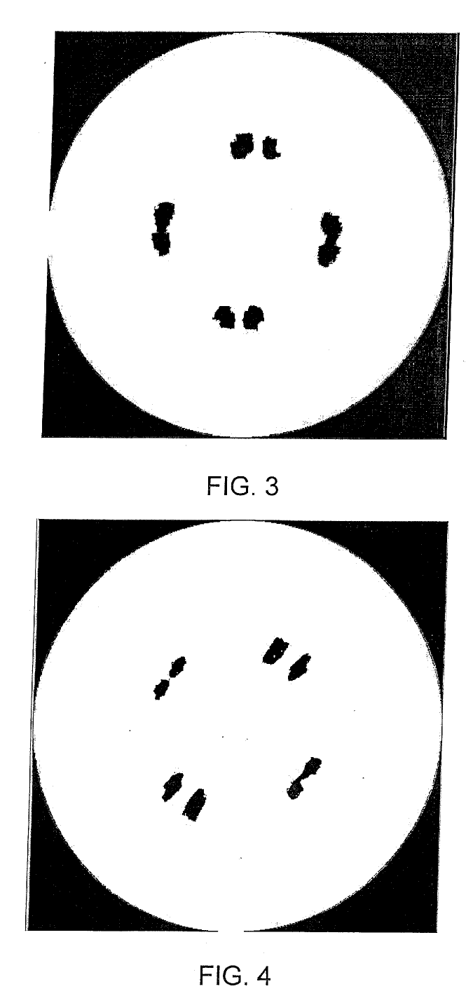

An x-ray diffraction pole figure for the Mo film on nickel is shown in FIG. 3 and the pole figure for Mo on copper is shown in FIG. 4.

The pole figures for Mo both substrate materials show nearly identical epitaxial growth relationships, despite the very low solubility of Mo in Cu and high solubility in Ni. The epitaxial relationship is Mo(011)//Ni(001) or Cu(001) out of plane and Mo(111)//Ni(110) or Cu(110) in the plane of the substrate.

### EXAMPLE 2

A thin layer of a transition metal that is soluble in both copper and the refractory metal, and that provides an intermediate lattice spacing to allow improved epitaxy can be used to improve the growth of the Group 5b or 6b film on copper.

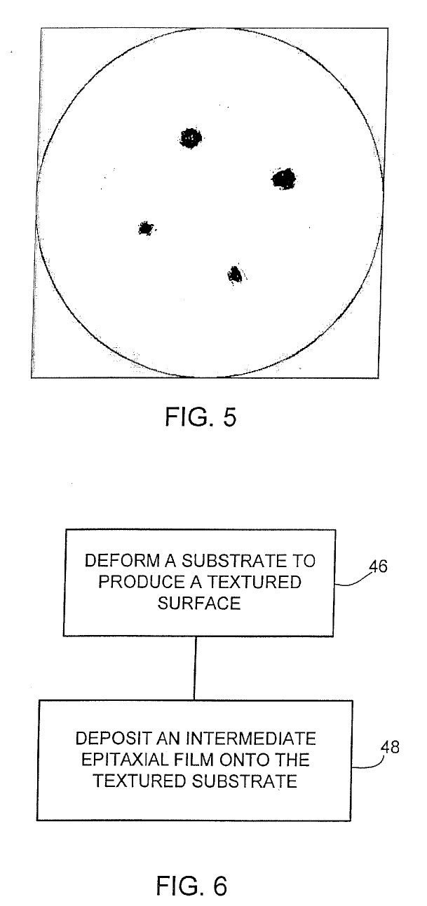

A 200 nm Ni film was deposited on the deformation textured copper substrate, immediately followed by deposition of a 200 nm Nb film using magnetron sputtering at 350 C and 0.1 nm/sec. The combination of the Ni film and Nb barrier provides a better lattice match than between the Mo and the Cu. The Ni film could not be observed following processing due to complete diffusion into the Cu substrate. A pole figure for the Nb film is shown in FIG. 5. The Nb film is (001) out of plane with Nb(110)//Cu(100) in plane.

### EXAMPLE 2a

A 200 nm Pd film was deposited on the Cu substrate at a temperature of 350 C at a growth rate of 0.2 nm/sec, followed immediately by a 200 nm thick Cr film deposited at 0.2 nm/sec, reproducing the example of Fritzemeier et al. (U.S. Pat. No. 6,730,410) Neither the Pd nor the Cr was biaxially textured.

In a parallel experiment, a 20 nm Pd film was deposited on the Cu substrate at a temperature of 350 C at a growth rate of 0.02 nm/sec, followed immediately by a 200 nm thick Cr film deposited at 0.05/nm/sec, both films exhibited very strong biaxial texture with Cr(001) out of plane and Cr(110)//Cu(100) in the plane of the substrate. Cr is an effective barrier to diffusion of elements from the Cu substrate into the semiconductor surface.

### EXAMPLE 3

A 200 nm Pd film was deposited on the Cu substrate at temperatures between 200 C and 400 C at a growth rate of 0.1 nm/sec, followed immediately by a 200 nm thick Al film and a 200 nm Cr film. The Cr is biaxially textured with Cr(001) out of plane and Cr(110)//Cu(100) in the plane of the substrate. Cr is an effective barrier to diffusion of elements from the Cu substrate into the semiconductor surface.

A germanium layer can be deposited directly on the chromium, which has an excellent lattice match for germanium growth.

### EXAMPLE 4

A molybdenum layer is deposited on the sample of Example 3 to provide an additional diffusion barrier, to provide thermal expansion control and to improve chemical compatibility to the germanium surface film. The Mo layer is typically deposited at 650-750 C to ensure thermal stability during semiconductor film growth. Growth rates from 0.1 nm/sec to over 1 nm/sec can be used. The Mo film is (001) out of plane and Mo(110)//Cu(100) in the plane of the substrate.

### EXAMPLE 5

A germanium film is grown on the sample of Example 2 through 4 to provide the surface for growth of a first layer of a semiconducting device. The germanium film can be either an undoped growth layer or can be doped to act as an active portion of the semiconductor device.

### EXAMPLE 6

A nitride film, such as VN, CrN, BN, is deposited on the surface of the copper of Example 1. The nitride film exhibits an epitaxial relationship with the surface of the underlying template.

### EXAMPLE 7

A molybdenum or germanium film is deposited on the surface of the nitride film of Example 4. The molybdenum or germanium film exhibits an epitaxial relationship with the underlying nitride film.

A first layer of a first p-n junction of the multijunction photovoltaic or a first semiconducting layer may be deposited directly on the epitaxial Ge layer.

### EXAMPLE 8

A biaxially textured oxide film is produced by ion beam assisted deposition. An epitaxial Mo film is deposited on the biaxially textured oxide film. Followed by Ge, followed by semiconductor.

### EXAMPLE 9

A multilayer article is prepared as described in the previous examples. The copper substrate is removed by processes known in the art such as chemical etching, oxidation, and electrochemical etching. A freestanding, biaxially textured foil suitable for the subsequent deposition of semiconducting layers is formed.

### EXAMPLE 10

The deposition of multiple intermediate layers is conducted sequentially as the substrate material moves from roll to roll in a stepwise or continuous fashion, producing a template for the growth of semiconductor materials and devices.

### EXAMPLE 11

The template of Example 10 is cut into pieces of a size and shape consistent with wafers used in conventional batch semiconductor processing equipment. Semiconductor devices are fabricated using conventional processes such as organo-metallic vapor phase epitaxy or molecular beam epitaxy.

### EXAMPLE 12

The template of Example 10 is transferred to a system for the roll to roll deposition of semiconductor material using conventional processes such as organo-metallic vapor phase epitaxy or molecular beam epitaxy or using advanced processes such as solution deposition and solid state epitaxy.

FIG. 6 schematically illustrates one embodiment of a thin-film photovoltaic template manufacturing process. A substrate is deformed 46 to produce a textured surface. Suitable materials for the deformation textured substrate, such as, for example, copper, nickel, and alloys thereof have been discussed above. Others will be apparent to those skilled in the art. An intermediate epitaxial film is deposited 48 onto the textured substrate. Examples of processes which can be used to deposit the intermediate epitaxial film include, but are not limited to, chemical vapor deposition, electroplating, sputtering, electron beam evaporation, molecular beam epitaxy, physical vapor deposition, and electrochemical deposition. This template manufacturing process can be used in a roll-to-roll manufacturing process, rather than in a traditional batch process, thereby potentially reducing the production costs and time.

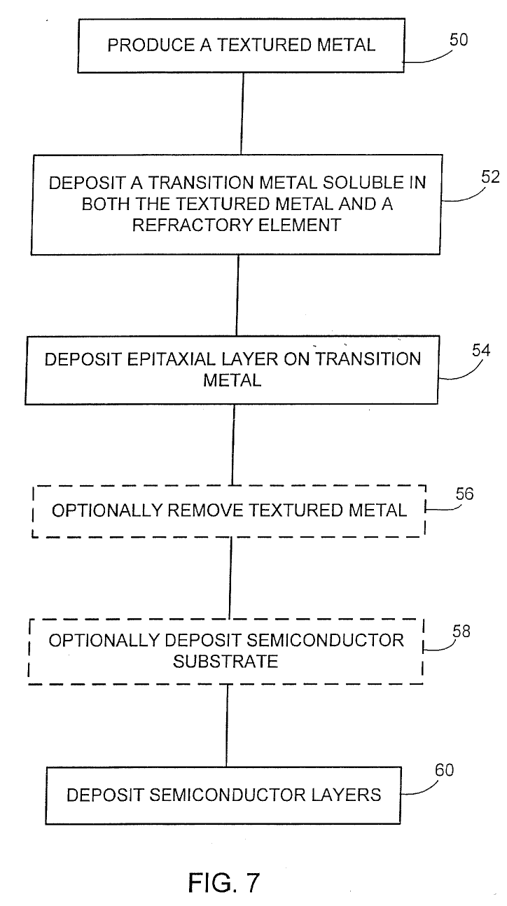

FIG. 7 schematically illustrates an embodiment of a semiconductor fabrication process. A textured metal is produced 50. A transition metal soluble in both the textured metal and a refractory element is deposited 52 on the textured metal. An epitaxial layer is deposited 54 on the transition metal. In this embodiment, both the transition metal and the epitaxial layer make up, at least in part, the intermediate epitaxial film which has been discussed above. At this point, the textured metal may be optionally removed 56, for example, by a chemical, oxidation, or electrochemical process. Further, a semiconductor substrate may optionally be deposited 58. Finally, semiconductor layers may be deposited 60 to form a semiconductor device, such as a photovoltaic device.

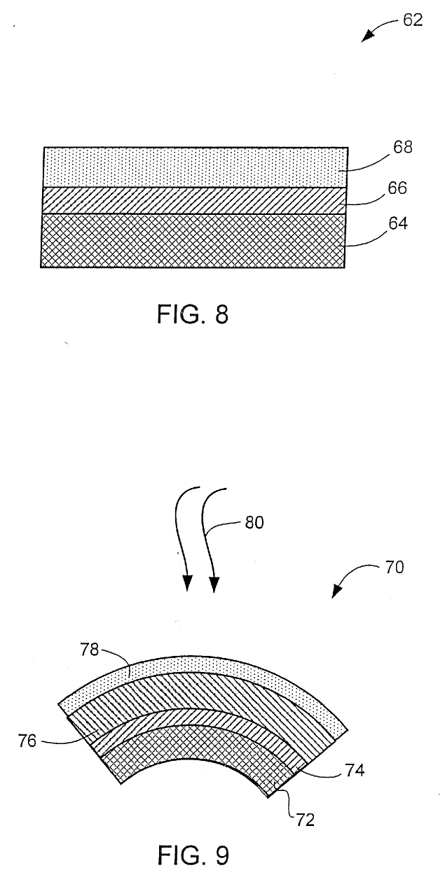

FIG. 8 schematically illustrates one embodiment of a photovoltaic device 62. The photovoltaic device has a deformation textured substrate 64 and an intermediate epitaxial film 66 coupled to the deformation textured substrate. A semiconductor layer 68 is coupled to the intermediate epitaxial film 66. Examples of a suitable semiconductor layer 68 material include, but are not limited to, doped silicon and gallium-arsenide. The semiconductor layer 68 can alternatively be a compound semiconductor or a series of compound semiconductor films forming multiple p-n junctions or tunnel junctions. As a further example, at least one of the junctions can be a GaAs p-n junction, an AlGaIAs tunnel junction, a GaIAs p-n junction, or a GaInP p-n junction. One advantage of using the embodiments of thin-film photovoltaic templates to create photovoltaic devices is that devices with large surface areas may be created, including, for example, surface areas in excess of 115 square centimeters. Smaller surface areas can be accommodated as well. The photovoltaic devices 62 may be made with a flexible deformation textured substrate in some embodiments

FIG. 9 schematically illustrates one embodiment of a flexible photovoltaic cell 70. The cell 70 has a flexible deformation textured substrate 72 and a metal intermediate epitaxial film 74 coupled to the flexible deformation textured substrate 72. A photovoltaic stack 76, containing at least one semiconductor, is coupled to the intermediate epitaxial film 74. At least one electrode 78 is coupled to the photovoltaic stack 76 to provide a path for electrical current from incident photons 80.

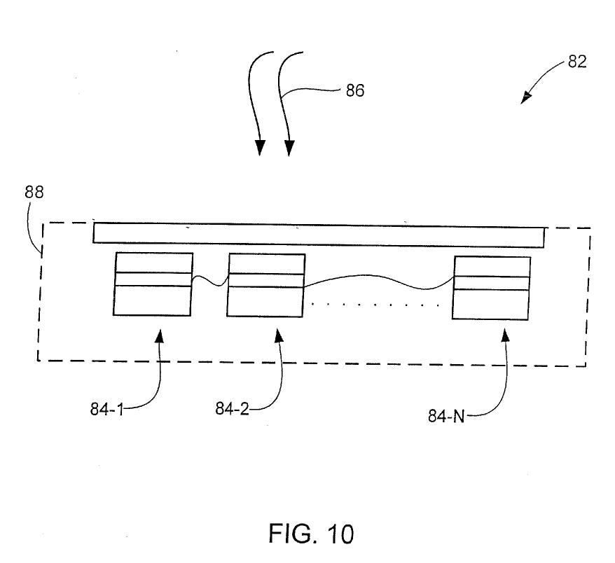

FIG. 10 schematically illustrates one embodiment of a photovoltaic module 82. The module 82 has an array of photovoltaic cells 84-1, 84-2, . . . , 84-N. Although the array is illustrated as being one-dimensional, the array could be two or three-dimensional in other embodiments. The photovoltaic cells 84 are electrically coupled together, either in series, in parallel, or a combination thereof to provide a desired voltage and current output when incident light 86 strikes the cells 84. The array of cells 84 may be supported by a support structure 88. The cells 84 may be constructed as described above.

Numerous advantages have been described above with regard to the embodied photovoltaic template and photovoltaic devices, and their equivalents. Having thus described several embodiments of the claimed invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and the scope of the claimed invention. Additionally, the recited order of the processing elements or sequences, or the use of numbers, letters, or other designations therefore, is not intended to limit the claimed processes to any order except as may be specified in the claims. Accordingly, the claimed invention is limited only by the following claims and equivalents thereto.

What is claimed is:

1. A template for growth of an anticipated semiconductor film, comprising:
a deformation textured substrate; and
an intermediate epitaxial film coupled to the deformation textured substrate, the intermediate epitaxial film being chemically compatible and substantially lattice matched with the anticipated semiconductor film.

2. The template of claim 1, wherein the deformation textured substrate comprises a surface approximating a single crystal surface.

3. The template of claim 1, wherein the deformation textured substrate comprises nickel.

4. The template of claim 1, wherein the deformation textured substrate comprises copper.

5. The template of claim 1, wherein the deformation textured substrate comprises a nickel alloy.

6. The template of claim 1, wherein the deformation textured substrate comprises a copper alloy.

7. The template of claim 1, wherein the intermediate epitaxial film comprises a Group IV element.

8. The template of claim 1, wherein the intermediate epitaxial film comprises a Group 5b element.

9. The template of claim 1, wherein the intermediate epitaxial film comprises a Group 6b element.

10. The template of claim 1, wherein the intermediate epitaxial film is directly coupled to the deformation textured substrate, the intermediate epitaxial film being chemically compatible and substantially lattice matched with the anticipated semiconductor film.

11. The template of claim 1, wherein the intermediate epitaxial film is indirectly coupled to the deformation textured substrate by a non-oxide intermediate layer, the intermediate epitaxial film being chemically compatible and substantially lattice matched with the anticipated semiconductor film.

12. The template of claim 1, wherein the intermediate epitaxial film comprises silicon or germanium.

13. The template of claim 1, wherein the intermediate epitaxial film comprises vanadium, chromium, niobium, molybdenum, tantalum, or tungsten.

14. The template of claim 1, wherein the intermediate epitaxial film comprises:
one or more of vanadium, chromium, niobium, molybdenum, tantalum, or tungsten; and
a transition metal.

15. The template of claim 1, wherein the intermediate epitaxial film comprises:
one or more of vanadium, chromium, niobium, molybdenum, tantalum, or tungsten; and
a noble metal.

16. The template of claim 1, wherein the intermediate epitaxial film comprises:
one or more of vanadium, chromium, niobium, molybdenum, tantalum, or tungsten; and
one or more of silicon or germanium.

17. The template of claim 1, wherein the intermediate epitaxial film comprises:
a nitride; and
one or more of vanadium, chromium, niobium, molybdenum, tantalum, or tungsten.

18. The template of claim 1, wherein the intermediate epitaxial film comprises:
a nitride; and
one or more of silicon or germanium.

19. The template of claim 1, further comprising a growth surface texture, and wherein the growth surface texture comprises grain boundary misorientations averaging less than 10 degrees.

20. The template of claim 1, wherein:
the deformation textured substrate comprises a face centered cubic metal; and
the intermediate epitaxial film comprises a body-centered-cubic metal.

21. The template of claim 1, wherein:
the deformation textured substrate comprises a face-centered-cubic metal; and
the intermediate epitaxial film comprises a diamond-centered-cubic metal.

22. A method of manufacturing a template for the growth of an anticipated semiconductor, comprising:
deforming a substrate to produce a textured surface; and
depositing an intermediate epitaxial film chemically compatible and substantially lattice matched with the anticipated semiconductor film.

23. The method of claim 22, wherein depositing the intermediate epitaxial film comprises a process selected from the group consisting of:
chemical vapor deposition;
electroplating;
sputtering;
electron beam evaporation;
molecular beam epitaxy;
physical vapor deposition;
solution deposition; and
electrochemical deposition.

24. A template for the growth of an anticipated semiconductor as produced by the process of claim 23.

25. The method of claim 22, further comprising a roll-to-roll manufacturing process, and wherein depositing the intermediate epitaxial film occurs as part of the roll-to-roll manufacturing process.

26. A photovoltaic device, comprising:
a semiconductor layer;
a deformation textured substrate; and
an intermediate epitaxial film coupled to the deformation textured substrate;
wherein:
the intermediate epitaxial film is chemically compatible and substantially lattice matched with the semiconductor layer; and
the semiconductor layer is epitaxially grown on the intermediate epitaxial film.

27. The photovoltaic device of claim 26, wherein the semiconductor layer comprises doped silicon.

28. The photovoltaic device of claim 26, wherein the semiconductor layer comprises gallium-arsenide.

29. The photovoltaic device of claim 26, wherein the semiconductor layer comprises a compound semiconductor or series of compound semiconductor films forming multiple p-n junctions.

30. The photovoltaic device of claim 26, wherein the semiconductor layer comprises a compound semiconductor or series of compound semiconductor films forming multiple p-i-n junctions.

31. The photovoltaic device of claim 26, wherein the semiconductor layer comprises a junction selected from the group consisting of:
a GaAs p-n junction;
an AlGaIAs tunnel junction;
a GaIAs p-n junction; and
a GaInP p-n junction.

32. The photovoltaic device of claim 31, wherein the intermediate epitaxial film comprises germanium.

33. The photovoltaic device of claim 32, wherein the deformation textured substrate comprises a flexible deformation textured substrate.

34. The photovoltaic device of claim 29, wherein the multiple p-n junctions comprise at least one germanium semiconductor junction.

35. The photovoltaic device of claim 26, wherein the deformation textured substrate comprises a flexible deformation textured substrate.

36. The photovoltaic device of claim 35, comprising a surface area in excess of 115 square centimeters.

37. A photovoltaic cell, comprising:
a flexible deformation textured substrate;
a metal intermediate epitaxial film coupled to the flexible deformation substrate;
a photovoltaic stack comprising a homojunction, heterojunction or multijunction photovoltaic stack coupled to the metal intermediate epitaxial film; and
at least one electrode coupled to the photovoltaic stack to provide a path for electrical current from incident photons.

38. The photovoltaic cell of claim 37, further comprising a first photoelectric conversion efficiency which is at least 80% of a second photoelectric conversion efficiency of a similar photovoltaic cell produced on a single crystal substrate.

39. A photovoltaic module, comprising:
a) an array of photovoltaic cells electrically coupled together and supported by a support structure;
b) a transparent protective cover protecting the array of photovoltaic cells; and
c) wherein at least one photovoltaic cell in the array of photovoltaic cells comprises:
1) a semiconductor layer;
2) deformation textured substrate; and
3) an intermediate epitaxial film coupled to the deformation textured substrate;
4) wherein:
i) the intermediate epitaxial film is chemically compatible and substantially lattice matched with the semiconductor layer; and
ii) the semiconductor later is epitaxially grown on the deformation textured substrate.

40. A method of manufacturing a photovoltaic device, comprising:
producing a textured metal;
depositing a transition metal soluble in both the textured metal and a refractory element;
depositing an epitaxial layer on the transition metal; and
depositing semiconductor layers on the epitaxial layer.

41. The method of claim 40, further comprising removing the textured metal.

42. The method of claim 40, further comprising depositing a semiconductor substrate prior to depositing the semiconductor layers.

43. A method of manufacturing a semiconductor device in a roll-to-roll process, comprising:
coupling an intermediate epitaxial film to a textured substrate; and
forming a semiconductor layer on the intermediate epitaxial film, wherein the intermediate epitaxial film is chemically compatible and substantially lattice matched with the semiconductor layer.

44. The method of claim 43, further comprising:
deforming a substrate to form the textured substrate.

45. The method of claim 44, further comprising:
annealing the textured substrate.

46. The method of claim 45, wherein the steps of:
1) annealing the textured substrate;
2) coupling the intermediate epitaxial film to the textured substrate; and
2) forming the semiconductor layer on the intermediate epitaxial film
occur sequentially as the substrate moves from a first roll to a second roll in a stepwise continuous fashion.

47. The method of claim 44, wherein the substrate comprises a substrate material selected from the group consisting of nickel, copper, a nickel alloy, and a copper alloy.

48. The method of claim 43, wherein the intermediate epitaxial film comprises a Group IV element.

49. The method of claim 43, wherein the intermediate epitaxial film comprises a Group 5b element.

50. The method of claim 43, wherein the intermediate epitaxial film comprises a Group 6b element.

51. The method of claim 43, further comprising:
prior to coupling the intermediate epitaxial film to the textured substrate, forming an intermediate layer on the textured substrate such that when the intermediate epitaxial film is coupled to the textured substrate, it will be indirectly coupled to the textured substrate.

52. The method of claim 43, wherein coupling the intermediate epitaxial film to the textured substrate comprises a process selected from the group consisting of:
chemical vapor deposition, electroplating, sputtering, electron beam evaporation, molecular beam epitaxy, physical vapor deposition, and electrochemical deposition.

53. The method of claim 43, wherein forming the semiconductor layer on the intermediate epitaxial film comprises a process selected from the group consisting of organometallic vapor phase epitaxy, molecular beam epitaxy, solution deposition, and solid state epitaxy.

54. The method of claim 43, wherein the steps of:
1) coupling the intermediate epitaxial film to the textured substrate; and
2) forming the semiconductor layer on the intermediate epitaxial film
occur sequentially as the textured substrate moves from a first roll to a second roll in a stepwise continuous fashion.

55. The method of claim 43, wherein the semiconductor layer comprises doped silicon.

56. The method of claim 43, wherein the semiconductor layer comprises gallium-arsenide.

57. The method of claim 43, wherein the semiconductor layer comprises a compound semiconductor or series of compound semiconductor films forming multiple p-n junctions.

58. The method of claim 43, wherein the semiconductor layer comprises a compound semiconductor or series of compound semiconductor films forming multiple p-i-n junctions.

59. The method of claim 43, wherein the semiconductor layer comprises a junction selected from the group consisting of a GaAs p-n junction, an AlGaIAs tunnel junction, a GaIAs p-n junction, and a GaInP p-n junction.

60. A semiconductor device as produced by the roll-to-roll process of claim 43.
